(19) United States
(12) Patent Application Publication
(10) Pub. No.: US 2009/0321988 A1
(43) Pub. Date: Dec. 31, 2009

(54) CHIP PACKAGING PROCESS

(75) Inventor: Po-Kai Hou, Tainan County (TW)

Correspondence Address: J C PATENTS, 4 VENTURE, SUITE 250, IRVINE, CA, 92618, US

(73) Assignee: CHIPMOS TECHNOLOGIES INC., Hsinchu (TW)

(21) Appl. No.: 12/555,159

(22) Filed: Sep. 8, 2009

Related U.S. Application Data
(62) Division of application No. 12/267,761, filed on Nov. 10, 2008.

(30) Foreign Application Priority Data
Feb. 15, 2008 (TW) 97105365

(51) Int. Cl. H01L 21/56

(52) U.S. Cl. 264/272.17

(57) ABSTRACT

In a chip packaging process, an upper and a lower mold chases are provided. A thickness adjusting film is then provided below the upper mold chase and/or above the lower mold chase. Next, a carrier is delivered to a position between the upper and the lower mold chases. A chip and a conductive line are disposed on the carrier, and the thickness adjusting film is located between the upper mold chase and the carrier and/or between the lower mold chase and the carrier. The upper and the lower mold chases are attached to define a cavity, and the thickness adjusting film is located on the surface of the upper mold chase and/or the surface of the lower mold chase. Thereafter, a molding compound is provided into the cavity by using a molding compound supplying unit. The upper and the lower mold chases and the thickness adjusting film are removed.

### CROSS-REFERENCE TO RELATED APPLICATION

This application is a divisional application and claims the priority benefit of U.S. application Ser. No. 12/267,761, filed on Nov. 10, 2008, now pending, which claims the priority benefit of Taiwan application serial no. 97105365, filed on Feb. 15, 2008. The entirety of each of the above-mentioned patent applications is hereby incorporated by reference herein and made a part of specification.

### BACKGROUND OF THE INVENTION

1. Field of the Invention

The invention generally relates to a chip packaging apparatus and a chip packaging process, and more particularly, to a chip packaging apparatus and a chip packaging process which can adjust the thickness of a molding compound and reduce the fabricating cost.

2. Description of Related Art

Along with the rapid development of technologies, integrated circuit (IC) devices have been broadly applied in various aspects of our daily life. Generally speaking, the fabrication of an IC is divided into three phases: the fabrication of silicon wafer, the fabrication of the IC, and the packaging of the IC.

Regarding the packaging of an IC, a chip is first placed on a lead frame. Then, the chip is electrically connected to a lead through a wire bonding process. Next, a molding compound is molded on the lead frame. The method for molding the molding compound on the lead frame includes following steps. First, the lead frame is placed between several mold chases. Then, the mold chases are attached to each other to define a cavity, and the lead frame is located in the cavity. Next, the molding compound is injected into the cavity through openings in the mold chases. After that, the mold chases are removed. By now, the fabrication of a chip package is completed.

However, requirement to chip packages of different thicknesses has been raised along with the development of techniques. Generally, a mold chases can only by used for fabricating chip packages of a fixed thickness, and the set of mold chases has to be changed to fabricate chip packages of different thicknesses. Accordingly, the fabricating cost is increased and process duration is prolonged.

### SUMMARY OF THE INVENTION

Accordingly, the invention is directed to a chip packaging apparatus which can reduce the fabricating cost.

The invention is also directed to a chip packaging process which can adjust the thickness of a molding compound.

The invention provides a chip packaging apparatus including an upper mold chase, a lower mold chase, a carrier delivering unit, a molding compound thickness adjusting unit, and a molding compound supplying unit. The lower mold chase is disposed below the upper mold chase. The carrier delivering unit delivers a carrier to a position between the upper mold chase and the lower mold chase. The molding compound thickness adjusting unit provides a thickness adjusting film between the upper mold chase and the carrier and/or between the lower mold chase and the carrier, and adjusts the thickness of a molding compound according to the thickness of the thickness adjusting film. The molding compound supplying unit is connected to the upper mold chase or the lower mold chase for providing the molding compound into a cavity defined by the upper mold chase and the lower mold chase.

According to an embodiment of the invention, when the upper mold chase and the lower mold chase are attached together, the thickness adjusting film may be located on the surface of the upper mold chase and/or the surface of the lower mold chase.

According to an embodiment of the invention, the upper mold chase may have an upper cavity.

According to an embodiment of the invention, the lower mold chase may have a lower cavity.

According to an embodiment of the invention, the material of the thickness adjusting film may be a polymer material.

According to an embodiment of the invention, the carrier may be a substrate or a lead frame.

The invention also provides a chip packaging process. First, an upper mold chase and a lower mold chase are provided. Then, a thickness adjusting film is provided below the upper mold chase and/or above the lower mold chase by using a molding compound thickness adjusting unit. Next, a carrier is delivered to a position between the upper mold chase and the lower mold chase by using a carrier delivering unit, wherein a chip and a conductive line are disposed on the carrier and the thickness adjusting film is located between the upper mold chase and the carrier and/or between the lower mold chase and the carrier. After that, the upper mold chase and the lower mold chase are attached together to define a cavity, and the thickness adjusting film is located on the surface of the upper mold chase and/or the surface of the lower mold chase. Thereafter, a molding compound is provided into the cavity by using a molding compound supplying unit. Next, the upper mold chase and the lower mold chase are removed, and at the same time, the thickness adjusting film is removed.

According to an embodiment of the invention, the upper mold chase may have an upper cavity.

According to an embodiment of the invention, the lower mold chase may have a lower cavity.

According to an embodiment of the invention, the material of the thickness adjusting film may be a polymer material.

According to an embodiment of the invention, the carrier may be a substrate or a lead frame.

In the invention, a thickness adjusting film of different thickness is provided on the surface of the mold chase before the molding compound is injected into the cavity. Thereby, chip packages of different thicknesses can be fabricated without changing the mold chase, and accordingly, the fabricating cost can be reduced and the process duration can be shortened.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are cross-sectional diagrams illustrating a procedure for fabricating a chip package according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

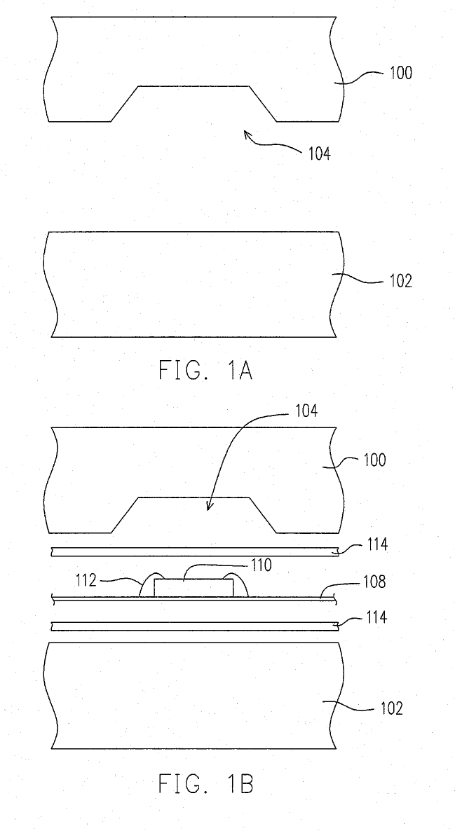

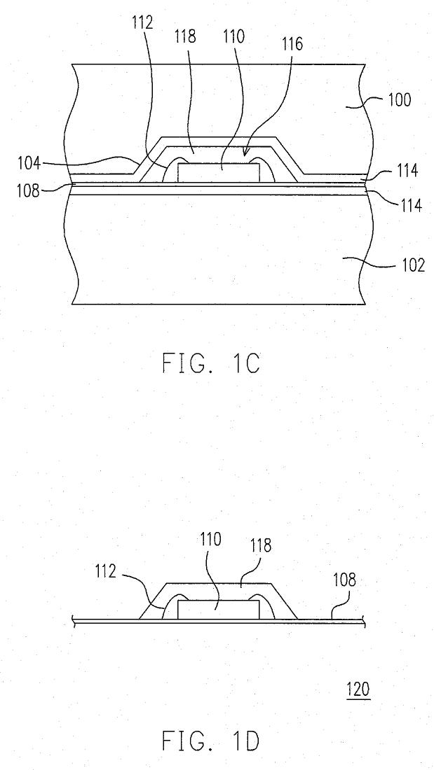

FIGS. 1A to 1D are cross-sectional diagrams illustrating a procedure for fabricating a chip package according to an embodiment of the invention. A quad flat non-leaded (QFN) package is described in the present embodiment as an example. First, as shown in FIG. 1A, an upper mold chase 100 and a lower mold chase 102 are provided. The upper mold chase 100 may have an upper cavity 104, and the lower mold chase 102 does not have any lower cavity. However, in another embodiment of the invention (not shown), the chip package, such as a ball grid array (BGA) package, a quad flat package (QFP), or a thin small outline package (TSOP), may have a lower cavity. A cavity for accommodating a chip to be packaged is defined when the upper mold chase 100 and the lower mold chase 102 are attached together.

Next, referring to FIG. 1B, a carrier 108 is delivered to a position between the upper mold chase 100 and the lower mold chase 102 by using a carrier delivering unit (not shown), wherein the carrier 108 may be a lead frame or a substrate. A chip 110 and a conductive line 112 are disposed on the carrier 108, and the chip 110 is electrically connected to a lead (now shown) via the conductive line 112 through a wire bonding process. A thickness adjusting film 114 is provided between the upper mold chase 100 and the carrier 108 and between the lower mold chase 102 and the carrier 108 by using a molding compound thickness adjusting unit (not shown) before the carrier is delivered to the position between the upper mold change and the lower mold chase. The material of the thickness adjusting film 114 may be a polymer material, and the thickness thereof can be adjusted according to the actual requirement. To be specific, because the size of the cavity defined by the upper mold chase 100 and the lower mold chase 102 is fixed, a thicker thickness adjusting film 114 is used if a thinner chip package is to be formed. Contrarily, a thinner thickness adjusting film 114 is used if a thicker chip package is to be formed.

It should mentioned herein that in the present embodiment, the thickness adjusting film 114 is provided between the upper mold chase 100 and the carrier 108 and between the lower mold chase 102 and the carrier 108. However, in another embodiment of the invention, the thickness adjusting film 114 may be provided only between the upper mold chase 100 and the carrier 108 or only between the lower mold chase 102 and the carrier 108 according to the actual requirement.

Next, referring to FIG. 1C, the upper mold chase 100 and the lower mold chase 102 are attached together to define a cavity 116. Part of the carrier 108 and the chip 110 and the conductive line 112 disposed on the carrier 108 are located in the cavity 116, and the thickness adjusting film 114 is located on respectively the surface of the upper mold chase 100 and the surface of the lower mold chase 102. After that, a molding compound 118 is provided into the cavity 116 through an opening (not shown) in the upper mold chase 100 and/or an opening (not shown) in the lower mold chase 102 by using a molding compound supplying unit (not shown). Since the thickness adjusting film 114 is formed on the surface of the upper mold chase 100 and the surface of the lower mold chase 102, when the molding compound 118 is injected into the cavity 116, the volume of the molding compound 118 is smaller than the capacity of the cavity 116, namely, the formed chip package can have a smaller thickness. In addition, by altering the thickness of the thickness adjusting film 114, a chip package of different thickness can be formed without changing the mold chase.

Thereafter, referring to FIG. 1D, the upper mold chase 100 and the lower mold chase 102 are removed, and at the same time, the thickness adjusting film 114 is removed, so as to form a chip package 120. It should be mentioned herein that because the thickness adjusting film 114 is removed while removing the upper mold chase 100 and the lower mold chase 102, a chip package of different thickness can be formed subsequently by simply providing another thickness adjusting film. Besides, the invention may also be applied to the fabrication of other chip packages, such as BGA packages, QFPs, or TSOPs.

In overview, according to the invention, a thickness adjusting film is provided on the surface of the mold chase before the molding compound is injected into the cavity. Thereby, chip packages of different thicknesses can be formed to meet the requirement of different electronic devices by adjusting the thickness of the thickness adjusting film. Moreover, chip packages of different thicknesses can be formed without changing the mold chase by using the chip packaging apparatus provided by the invention. Thereby, the fabricating cost can be reduced and process duration can be shortened.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A chip packaging process, comprising:
providing an upper mold chase and a lower mold chase;
providing a thickness adjusting film below the upper mold chase and/or above the lower mold chase by using a molding compound thickness adjusting unit;
delivering a carrier to a position between the upper mold chase and the lower mold chase by using a carrier delivering unit, wherein a chip and a conductive line are disposed on the carrier, and the thickness adjusting film is located between the upper mold chase and the carrier and/or between the lower mold chase and the carrier;
attaching the upper mold chase and the lower mold chase together to define a cavity and locating the thickness adjusting film on a surface of the upper mold chase and/or a surface of the lower mold chase;
providing a molding compound into the cavity by using a molding compound supplying unit; and
removing the upper mold chase and the lower mold chase and removing the thickness adjusting film.

2. The chip packaging process according to claim 1, wherein the upper mold chase has an upper cavity.

3. The chip packaging process according to claim 1, wherein the lower mold chase has a lower cavity.

4. The chip packaging process according to claim 1, wherein the material of the thickness adjusting film comprises a polymer material.

5. The chip packaging process according to claim 1, wherein the carrier comprises a substrate or a lead frame.
